(19) United States
(12) Patent Application Publication
(10) Pub. No.: US 2025/0287601 A1
(43) Pub. Date: Sep. 11, 2025

(54) FERROELECTRIC MEMORY DEVICE AND MANUFACTURING METHOD OF FERROELECTRIC MEMORY DEVICE

(71) Applicant: SK hynix Inc., Icheon-si Gyeonggi-do (KR)

(72) Inventor: Sunghyun Yoon, Icheon-si Gyeonggi-do (KR)

(73) Assignee: SK hynix Inc., Icheon-si Gyeonggi-do (KR)

(21) Appl. No.: 18/793,473

(22) Filed: Aug. 2, 2024

(30) Foreign Application Priority Data
Mar. 5, 2024 (KR) 10-2024-0031437

(51) Int. Cl. H10B 51/20; H01L 29/66; H01L 29/78

(52) U.S. Cl. CPC H10B 51/20; H10D 30/0415; H10D 30/701

(57) ABSTRACT

The present disclosure relates to a ferroelectric memory device and a method of manufacturing the ferroelectric memory device. The ferroelectric memory device includes a dielectric layer including a plurality of ferroelectric areas alternately arranged with a plurality of non-ferroelectric areas in a first direction, the dielectric layer having a tubular structure, a channel layer extending in the first direction on an inner wall of the dielectric layer, and a gate stack structure including a plurality of conductive layers surrounding the plurality of ferroelectric areas of the dielectric layer, and wherein the plurality of conductive layers are spaced apart in the first direction.

### CROSS-REFERENCE TO RELATED APPLICATION

The present application claims priority under 35 U.S.C. § 119(a) to Korean patent application number 10-2024-0031437 filed on Mar. 5, 2024, in the Korean Intellectual Property Office, the entire contents of which application is incorporated herein by reference.

### BACKGROUND

### 1. Technical Field

The present disclosure relates to a semiconductor memory device and a method of manufacturing the semiconductor memory device, including but not limited to a ferroelectric memory device and a method of manufacturing the ferroelectric memory device.

### 2. Related Art

Semiconductor memory devices are applicable to electronic devices in various fields such as automobiles, medical care, and data centers, as well as small electronic devices. Accordingly, an increasing demand for semiconductor memory devices exists.

A semiconductor memory device includes a plurality of memory cells for storing data. Three-dimensional memory devices have been proposed to increase integration density of memory cells within a unit area of a substrate. The three-dimensional memory devices include memory cells that are stacked, for example, in a vertical direction over the substrate.

### SUMMARY

According to an embodiment, a ferroelectric memory device may include a dielectric layer including a plurality of ferroelectric areas alternately arranged with a plurality of non-ferroelectric areas in a first direction, the dielectric layer having a tubular structure, a channel layer extending in the first direction on an inner wall of the dielectric layer, and a gate stack structure including a plurality of conductive layers surrounding the plurality of ferroelectric areas of the dielectric layer, wherein the plurality of conductive layers are spaced apart in the first direction.

According to an embodiment, a method of manufacturing a ferroelectric memory device may include forming a stacked structure including a plurality of first material layers alternately arranged with a plurality of second material layers in a stacking direction, forming a hole passing through the stacked structure by etching the plurality of first material layers and the plurality of second material layers, forming a ferroelectric layer in the hole, the ferroelectric layer having a tubular structure extending in the stacking direction, forming a channel layer extending in the stacking direction and covering an inner wall of the ferroelectric layer, forming a slit passing through the stacked structure by etching the plurality of first material layers and the plurality of second material layers, replacing the plurality of second material layers with a plurality of conductive layers through the slit, removing the plurality of first material layers through the slit such that an opening is formed between consecutive conductive layers of the plurality of conductive layers in the stacking direction, and injecting a dopant into areas of the ferroelectric layer exposed through the opening such that a plurality of non-ferroelectric areas is formed in the ferroelectric layer.

According to an embodiment, a ferroelectric memory device may include a gate stack structure including a plurality of conductive layers spaced apart in a first direction; a dielectric layer disposed within the gate structure and including a plurality of ferroelectric areas forming memory cells alternately arranged with a plurality of non-ferroelectric areas in the first direction; and a channel layer disposed on an inner wall of the dielectric layer.

### BRIEF DESCRIPTION OF THE DRAWINGS

FIG. 1 is a circuit diagram of a memory cell string of a ferroelectric memory device according to an embodiment of the present disclosure;

FIG. 2 is a perspective view of a ferroelectric memory device according to an embodiment of the present disclosure;

FIG. 3 is a polarization-electric field hysteresis curve in a ferroelectric area according to an embodiment of the present disclosure;

FIG. 4A and FIG. 4B are diagrams illustrating a polarization state of a memory cell according to an embodiment of the present disclosure;

FIG. 5A and FIG. 5B are cross-sectional diagrams of a ferroelectric memory device according to an embodiment of the present disclosure;

FIG. 6A to FIG. 6C are cross-sectional diagrams of a ferroelectric memory device according to an embodiment of the present disclosure;

FIG. 7A to FIG. 7E are cross-sectional diagrams showing a gate stack structure of a ferroelectric memory device formed using processes of forming a gate stack structure of a ferroelectric memory device according to an embodiment of the present disclosure;

FIG. 8 shows cross-sections illustrating a non-ferroelectric area of a ferroelectric memory device formed using processes of forming a non-ferroelectric area of a ferroelectric memory device according to embodiments of the present disclosure;

FIG. 9 and FIG. 10 are cross-sectional diagrams illustrating a non-ferroelectric area of a ferroelectric memory device formed using post-processing of a non-ferroelectric area according to embodiments of the present disclosure;

FIG. 11 is a cross-sectional diagram illustrating an interface oxide layer formed using a process according to an embodiment of the present disclosure; and

FIG. 12 is a block diagram illustrating an electronic system according to an embodiment of the present disclosure.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Terms such as “first” and “second” are used to distinguish between various elements and do not imply size, order, priority, quantity, or importance of the elements. For example, a first element may be named as a second element in one example, and the second element may be named as a first element in another example. Terms such as “vertical,” “horizontal,” “top,” “over,” “on,” “side,” “upper,” “lower,” “higher,” “column,” “row,” “inner,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas.

As interest in next generation memory devices increasingly grows, various technological advancements have been made such that in association with three-dimensional semiconductor memory devices, use of ferroelectric layers in data storage areas of memory cells replaces charge trap layers. According to embodiments of the present disclosure, a ferroelectric memory device capable of improving operating reliabilities and a method of manufacturing the ferroelectric memory device is described.

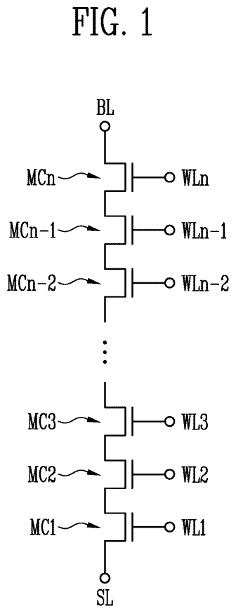

FIG. 1 is a circuit diagram of a memory cell string of a ferroelectric memory device according to an embodiment of the present disclosure.

Referring to FIG. 1, a memory cell array of a ferroelectric memory device includes a plurality of memory cell strings. Each of the memory cell strings includes a plurality of memory cells (first to nth memory cells MC1 to MCn) coupled in series between a corresponding bit line BL and a source layer SL, where n is a natural number of 2 or more. According to an embodiment, in the plurality of memory cells MC1 to MCn, the first memory cell MC1 adjacent to the source layer SL is electrically coupled to the source layer SL, and the nth memory cell MCn is electrically coupled to the bit line BL. The present disclosure is not limited to this example. According to an embodiment, either or both of the bit line BL and the source layer SL is electrically coupled to a memory cell string via a select transistor.

Each of the plurality of memory cells MC1 to MCn is composed of ferroelectric electric-effect transistors that use ferroelectrics as data storage areas. The memory cells MC1 to MCn have low-power high-speed operating characteristics in accordance with ferroelectrics properties.

The plurality of memory cells MC1 to MCn is coupled to a plurality of word lines WL1 to WLn, respectively. Each of the word lines WL1 to WLn serves as a gate electrode for a corresponding memory cell. Each of the word lines WL1 to WLn corresponds to one of a plurality of conductive layers that are disposed over a substrate (not shown). The plurality of memory cells MC1 to MCn are formed at intersections between the plurality of conductive layers and a channel layer that passes through the plurality of conductive layers.

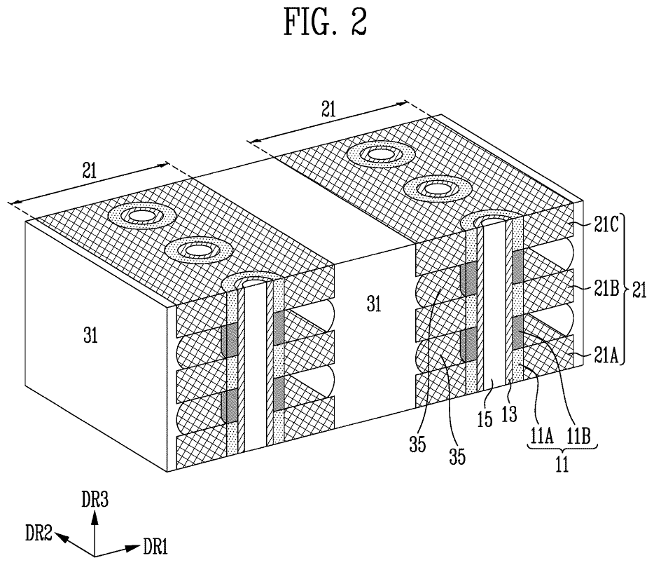

FIG. 2 is a perspective view of a ferroelectric memory device according to an embodiment of the present disclosure.

Referring to FIG. 2, the ferroelectric memory device includes a plurality of gate stack structures 21, a plurality of dielectric layers 11, and a plurality of channel layers 13.

The plurality of gate stack structures 21 are separated from each other in a first direction DR1 and extend in a second direction DR2. Each of the gate stack structures 21 includes a plurality of conductive layers 21A, 21B, and 21C spaced apart from each other in a third direction DR3 and are stacked on top of each other. The plurality of conductive layers 21A, 21B, and 21C are disposed over a substrate (not shown). The first direction DR1, the second direction DR2, and the third direction DR3 may correspond to the X-axis direction, the Y-axis direction, and the Z-axis direction, respectively.

The plurality of conductive layers 21A, 21B, and 21C may include at least one of a doped semiconductor material, a conductive metal nitride, metal, and a metal-semiconductor compound. The doped semiconductor material may include doped silicon, doped germanium, and the like. Each of the plurality of conductive layers 21A, 21B, and 21C may include conductive metal nitride and metal. The conductive metal nitride may extend on upper and lower surfaces and a sidewall of the metal. Examples of the metal nitride include titanium nitride, tantalum nitride, and the like. Examples of the metal include tungsten, titanium, tantalum, molybdenum, and the like. Examples of the metal-semiconductor compound include tungsten silicide, cobalt silicide, titanium silicide, and the like.

A sidewall of the gate stack structure 21 is covered by an insulating layer 31. The insulating layer 31 is disposed between neighboring gate stack structures 21. The insulating layer 31 may include silicon oxide.

Each of air-gaps 35 is formed or disposed between neighboring or consecutive conductive layers in the third direction DR3, for example, between the conductive layers 21A and 21B or between the conductive layers 21B and 21C. The insulating layer 31 blocks the air-gap 35 from outside the ferroelectric memory device. The insulating layer 31 is adjacent to the air-gap 35. A dielectric constant of the air-gap 35 may have a value that is similar to or the same as a dielectric constant in a vacuum state. A parasitic capacitance between neighboring conductive layers in the third direction DR3 is reduced compared to the example where other dielectrics such as a silicon oxide are disposed between neighboring or consecutive conductive layers in the third direction DR3.

The plurality of dielectric layers 11 is arranged in a plurality of rows and a plurality of columns. Each of the columns of dielectric layers 11 are arranged in a line in the first direction DR1. Each of the rows of dielectric layers 11 are arranged in a line in the second direction DR2. Each of the gate stack structures 21 include dielectric layers that form at least one row and extend in the second direction DR2. The rows controlled by each gate stack structure 21 are not limited to the example shown in the drawings. According to an embodiment, each gate stack structure 21 surrounds the dielectric layers 11 that form at least two rows.

Each of the dielectric layers 11 has a tubular structure that extends in the third direction DR3. The third direction DR3 may correspond to a longitudinal direction of the dielectric layer 11. A base material of the dielectric layer 11 includes a material that exhibits the characteristic of ferroelectricity, for example, when processed into a thin film of 10 nm or less. According to an embodiment, the dielectric layer 11 may include a hafnium oxide-based material or a hafnium oxide-based material doped with a dopant. The dopant may include one or more of zirconium (Zr), silicon (Si), aluminum (Al), gadolinium (Gd), yttrium (Y), lanthanum (La), and strontium (Sr).

The dielectric layer 11 includes a plurality of ferroelectric areas 11A alternately arranged with a plurality of non-ferroelectric areas 11B. Each of the ferroelectric areas 11A is an area having spontaneous polarization characteristics. Each of the non-ferroelectric areas 11B is an area where depolarization occurs when an electric field is not applied. The non-ferroelectric area 11B includes at least one of an antiferroelectric area and a paraelectric area.

The plurality of channel layers 13 correspond to the plurality of dielectric layers 11. Each of the channel layers 13 extends along an inner wall of a corresponding dielectric layer 11. The channel layer 13 includes an end that is coupled to the source layer SL as shown in FIG. 1. The channel layer 13 extends in the third direction DR3, such as a longitudinal direction, toward the bit line BL as shown in FIG. 1. The channel layer 13 may include a semiconductor material. According to an embodiment, the channel layer 13 may include silicon. The channel layer 13 may have a tubular structure. According to an embodiment, a central area of the channel layer 13 may be filled with a core insulating layer 15. The present disclosure is not limited to this example. The central area of the channel layer 13 may include an electrode.

Memory cells are formed at intersections between the plurality of channel layers 13 and the plurality of conductive layers 21A, 21B, and 21C. The ferroelectric areas 11A of the dielectric layer 11 serve as data storage areas of the memory cells.

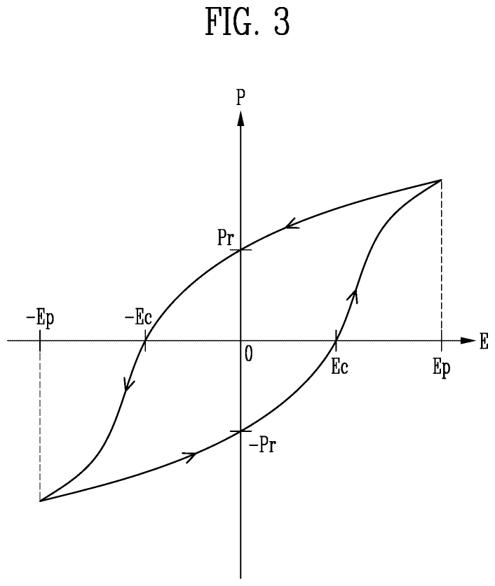

FIG. 3 is a polarization-electric field hysteresis curve in a ferroelectric area according to an embodiment of the present disclosure.

Referring to FIG. 3, when an external electric field applied to a ferroelectric area having a negative polarization state is positive and is greater than or equal to a first coercive electric field Ec, the polarization of the ferroelectric area is inverted. When the external electric field applied to the ferroelectric area is increased from the first coercive electric field Ec to a first saturation electric field Ep or greater and the external electric field is subsequently decreased to zero, the ferroelectric area has a first remnant polarization Pr. The polarization of the ferroelectric area is inverted when an external electric field applied to a ferroelectric area having a positive polarization state is negative and has an absolute value greater than or equal to an absolute value of a second coercive electric field −Ec. When the absolute value of the negative external electric field applied to the ferroelectric area is increased to a value greater than or equal to the absolute value of the second coercive electric field −Ec and is subsequently decreased to zero, the ferroelectric area has a second remnant polarization −Pr.

By utilizing these hysteresis characteristics of the ferroelectric area, logic data corresponding to the remnant polarization of a memory cell are stored. By sensing a current or a voltage according to a remnant polarization state of a memory cell, logic data stored in the memory cell is read out.

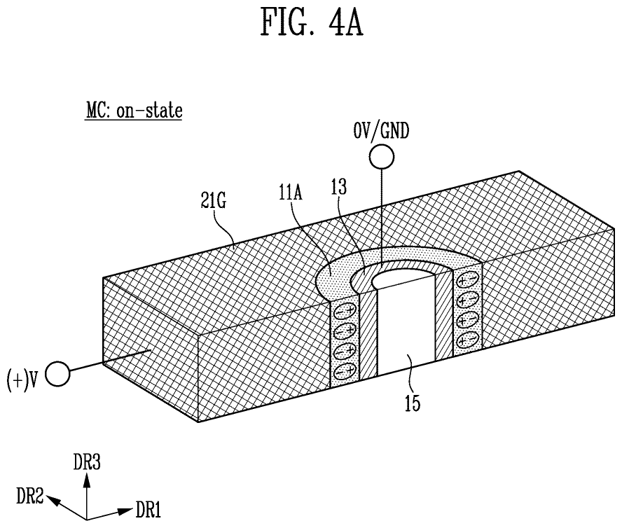

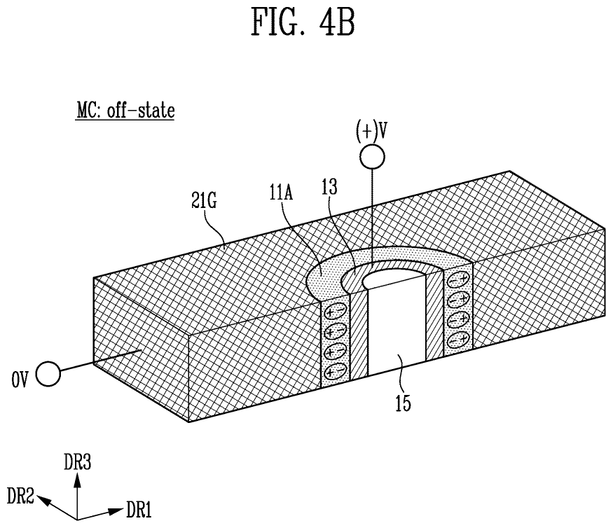

FIG. 4A and FIG. 4B are diagrams illustrating a polarization state of a memory cell according to an embodiment of the present disclosure.

Referring to FIG. 4A and FIG. 4B, a memory cell MC is formed at an intersection between the channel layer 13 and a conductive layer 21G, and an on-state or an off-state of the memory cell MC is determined based on a polarization direction in a ferroelectric area 11A. The channel layer 13 extends toward the bit line BL from the source layer SL as shown in FIG. 1 and includes a channel region corresponding to the memory cell MC. The conductive layer 21G is one of the plurality of conductive layers 21A, 21B, and 21C of the gate stack structure 21 as shown in FIG. 2.

An external electric field is applied to the ferroelectric area 11A by a voltage applied to the conductive layer 21G and a voltage applied to the channel region of the channel layer 13. The voltage applied to the channel region of the channel layer 13 is transferred from the bit line BL shown in FIG. 1 or the source layer SL shown in FIG. 1.

Referring to FIG. 4A, a higher voltage is applied to the conductive layer 21G than the voltage applied to the channel layer 13 such that an external electric field greater than or equal to an absolute value of a coercive electric field is applied to the ferroelectric area 11A. According to an embodiment, an external electric field applied to the ferroelectric area 11A is positive by applying 0V or a ground voltage GND to the channel layer 13 and applying a positive voltage to the conductive layer 21G, and the external electric field greater than or equal to the absolute value of the coercive electric field is applied to the ferroelectric area 11A by controlling the voltage applied to the conductive layer 21G. Radially-outward polarization results from a radially-inward external electric field applied to the ferroelectric area 11A, where the radially-outward polarization and the radially-inward external electric field are referenced with respect to the center of the core insulating layer 15 within the channel layer 13. When the external electric field is eliminated or no longer applied, the ferroelectric area 11A has remnant polarization in the radially-outward direction. A state in which the ferroelectric area 11A has a remnant polarization in the radially-outward direction is an on-state where logic data “0” is written. An energy band of the channel layer 13 is increased during the on-state. As a result, when data stored in the memory cell MC is read by controlling the voltages applied to the conductive layer 21G and the channel layer 13 such that an electric field less than the absolute value of the coercive electric field is formed in the ferroelectric area 11A, currents easily flow between the ferroelectric area 11A and the channel layer 13 due to a low potential barrier of the channel layer 13. Accordingly, the data stored in the memory cell MC is read out.

Referring to FIG. 4B, a higher voltage is applied to the channel layer 13 than the conductive layer 21G such that an external electric field greater than an absolute value of a coercive electric field is applied to the ferroelectric area 11A. According to an embodiment, by applying 0V to the conductive layer 21G and applying a positive voltage to the channel layer 13, an external field applied to the ferroelectric area 11A is negative. By controlling the voltage applied to the channel layer 13, the absolute value of an external electric field greater than or equal to the absolute value of the coercive electric field is applied to the ferroelectric area 11A. Radially-inward polarization results from a radially-outward external electric field applied to the ferroelectric area 11A, where the radially-outward external electric field and the radially-inward polarization are referenced with respect to the center of the core insulating layer 15 within the channel layer 13. When the external electric field is eliminated or no longer applied, the ferroelectric area 11A has remnant polarization in the radially-inward direction. A state in which the ferroelectric area 11A has a remnant polarization in the radially-inward direction is an off-state where logic data “1” is written. An energy band of the channel layer 13 is increased during the off-state. As a result, current flowing between the ferroelectric area 11A and the channel layer 13 is suppressed when data is read by controlling the voltages applied to the conductive layer 21G and the channel layer 13 such that an electric field less than the absolute value of the coercive electric field is formed in the ferroelectric area 11A. Accordingly, the data stored in the memory cell MC is read out.

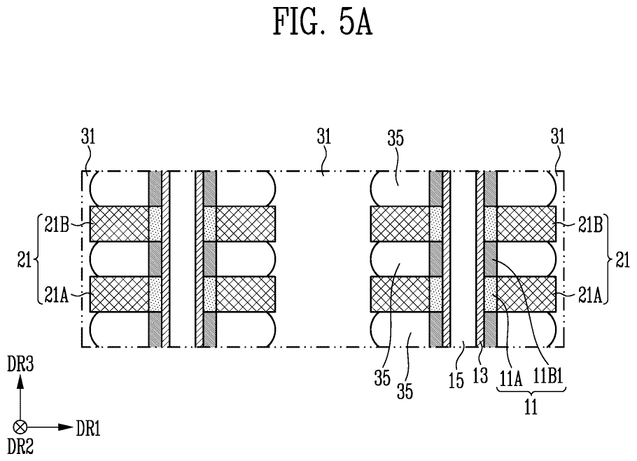

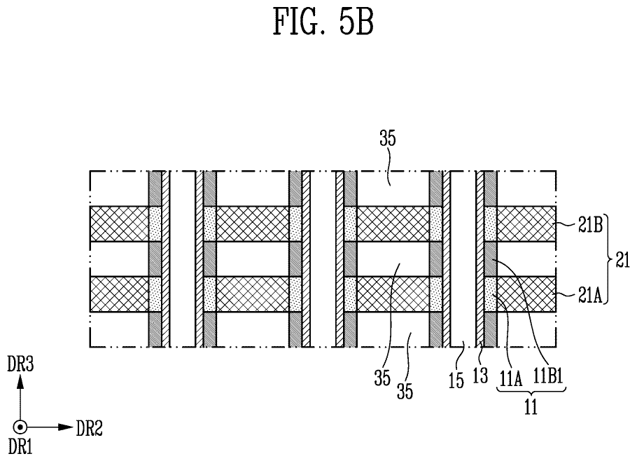

FIG. 5A and FIG. 5B are cross-sectional diagrams of a ferroelectric memory device according to an embodiment of the present disclosure.

FIG. 5A is a cross-sectional diagram of a ferroelectric memory device taken along a line extending in the first direction DR1. FIG. 5B is a cross-sectional diagram of a ferroelectric memory device taken along a line extending in the second direction DR2.

Referring to FIG. 5A and FIG. 5B, the conductive layers 21A and 21B of the gate stack structure 21 are alternately arranged with the air-gaps 35 in the third direction DR3. The air-gaps 35 are blocked from outside the ferroelectric memory device by an insulating layer 31 and extend between consecutive or successive dielectric layers 11 in the second direction DR2.

Each of the dielectric layers 11 includes the ferroelectric areas 11A alternately arranged with non-ferroelectric areas 11B1 in the third direction DR3. The ferroelectric area 11A and the non-ferroelectric area 11B1 are distinguished from each other on the basis of a difference in dopant concentration in hafnium-based materials forming the dielectric layer 11. The non-ferroelectric area 11B1 may include at least one of an antiferroelectric area and a paraelectric area.

The non-ferroelectric area 11B1 includes a dopant at a higher concentration than the concentration of dopant of the ferroelectric area 11A and contacts the channel layer 13. According to an embodiment, the ferroelectric area 11A may include hafnium oxide (HfO₂) and the non-ferroelectric area 11B may include silicon-doped hafnium oxide (HSO). According to another embodiment, each of the ferroelectric area 11A and the non-ferroelectric area 11B1 may include a hafnium oxide doped with silicon. The concentration of the silicon referred to as “Si/(Hf+Si)” is controlled to be higher in the non-ferroelectric area 11B1 than in the ferroelectric area 11A. The concentration of silicon in the ferroelectric area 11A is controlled to be in a range where the ferroelectricity of the ferroelectric area 11A is maintained and operable as a memory layer. According to an embodiment, the concentration of the silicon may be 4% or greater and less than 9% in the ferroelectric area 11A and may be 9% or more in the non-ferroelectric area 11B1.

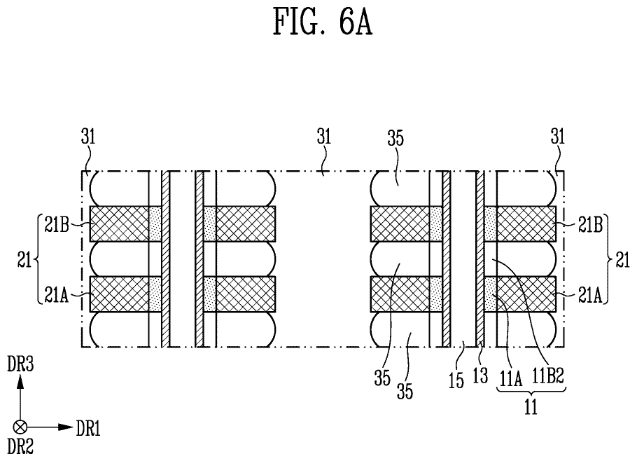

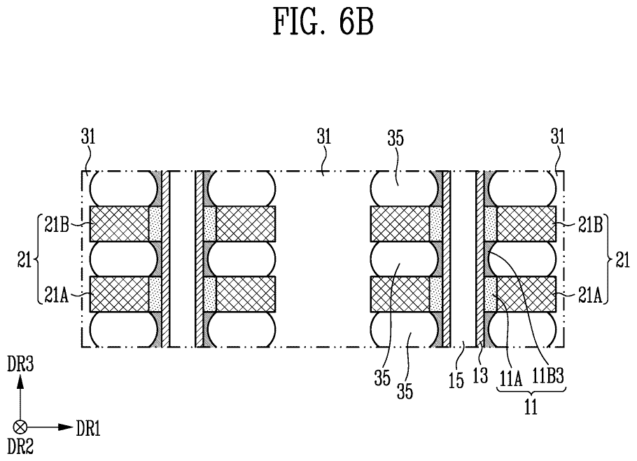

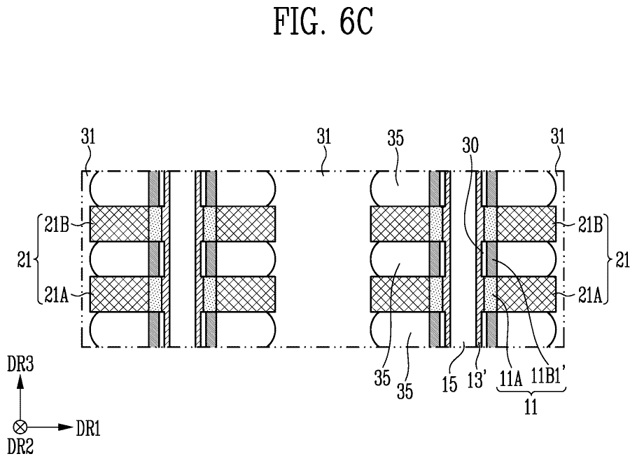

FIG. 6A to FIG. 6C are cross-sectional diagrams of a ferroelectric memory device according to embodiments of the present disclosure. FIG. 6A to FIG. 6C are cross-sectional diagrams illustrating a ferroelectric memory device taken along a line extending in the first direction DR1.

Referring to FIG. 6A, the dielectric layer 11 includes the ferroelectric areas 11A and non-ferroelectric areas 11B2. The non-ferroelectric area 11B2 has a different crystal system or structure than the ferroelectric area 11A. The non-ferroelectric area 11B2 includes at least one of an antiferroelectric area and a paraelectric area. According to an embodiment, the ferroelectric area 11A may include an orthorhombic crystal phase, the antiferroelectric area may include a tetragonal crystal phase, and the paraelectric area may include a monoclinic crystal phase.

Referring to FIG. 6B, the dielectric layer 11 includes the ferroelectric areas 11A and non-ferroelectric areas 11B3. The ferroelectric areas 11A and the non-ferroelectric areas 11B3 are distinguished from each other based on the difference in concentration of dopants in hafnium-based materials forming the dielectric layer 11. The non-ferroelectric area 11B3 has a concave outer wall that faces in a direction away from the channel layer 13.

Referring to FIG. 6C, the dielectric layer 11 includes the ferroelectric areas 11A and non-ferroelectric areas 11B1′. Interface oxide layers 30 are interposed between the non-ferroelectric areas 11B1′ and a channel layer 13′. The ferroelectric areas 11A and the non-ferroelectric areas 11B1′ are distinguished from each other on the basis of the difference in concentration of dopants in hafnium-based materials forming the dielectric layer 11 as described with reference to FIG. 5A and FIG. 5B. The interface oxide layer 30 may include silicon dioxide SiO₂.

Though not shown, the interface oxide layer 30 may be interposed between the non-ferroelectric area 11B2 and the channel layer 13 as shown in FIG. 6A or between the non-ferroelectric area 11B3 and the channel layer 13 as shown in FIG. 6B.

Referring to FIG. 5A, FIG. 6A, FIG. 6B, and FIG. 6C, each of the channel layers 13 or 13′ and the core insulating layer 15 includes a first area surrounded by the ferroelectric area 11A of the dielectric layer 11 and a second area surrounded by the non-ferroelectric area 11B, 11B2, 11B3, or 11B1′. The first area of the channel layer 13 or 13′ contacts the ferroelectric area 11A of the dielectric layer 11.

Each of the conductive layers 21A and 21B of the gate stack structure 21 surrounds the ferroelectric area 11A of the corresponding dielectric layer 11. The air-gaps 35 are disposed between the non-ferroelectric areas 11B1, 11B2, 11B3, or 11B1′ and the insulating layers 31.

The non-ferroelectric area 11B1, 11B2, 11B3, or 11B1′ are interposed between consecutive ferroelectric areas 11A in the third direction DR3 to divide the ferroelectric area 11A into units of memory cells. As a result, spontaneous polarization between consecutive memory cells in the third direction DR3 is mitigated or prevented, thereby reducing the effect of disturbance caused by the spontaneous polarization.

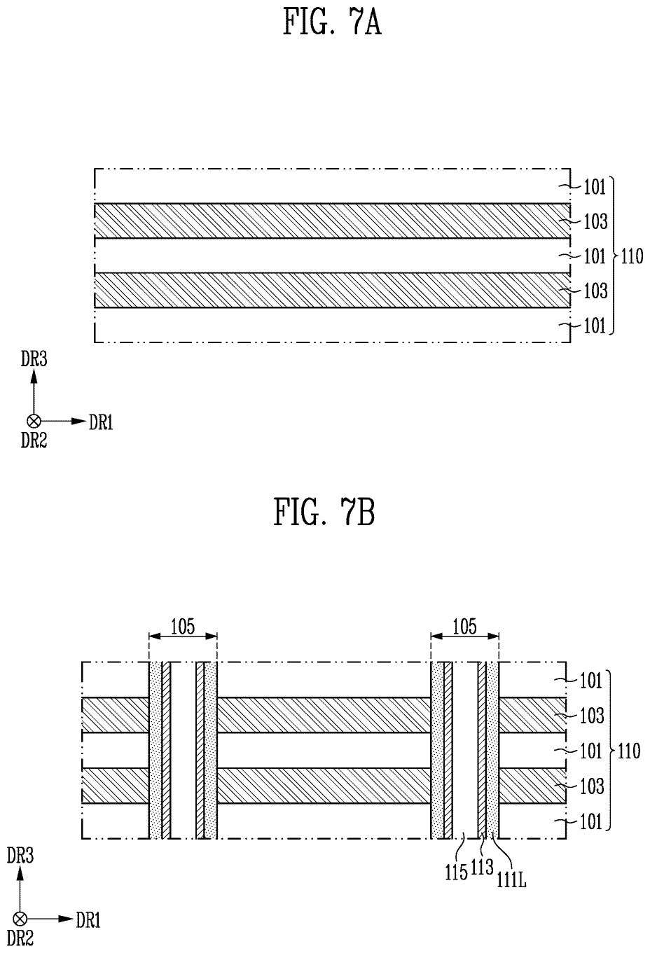

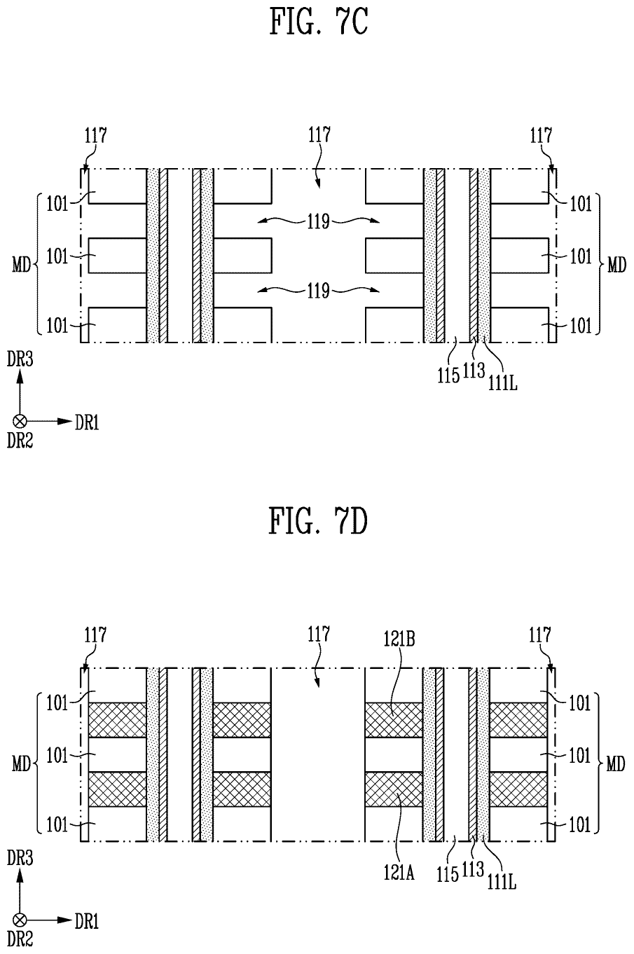

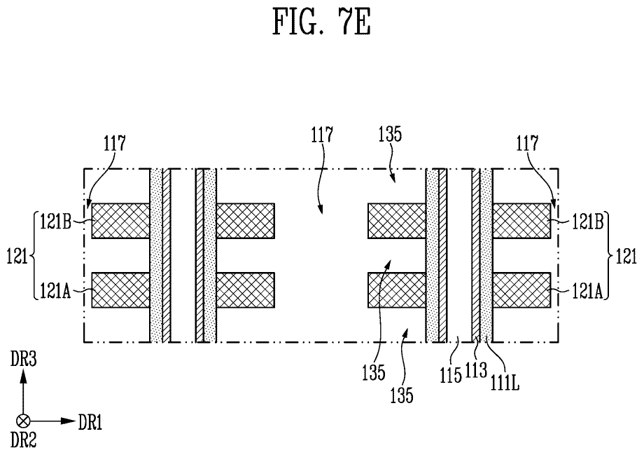

FIG. 7A to FIG. 7E are cross-sectional diagrams showing a gate stack structure of a ferroelectric memory device formed using processes of forming a gate stack structure of a ferroelectric memory device according to an embodiment of the present disclosure.

Referring to FIG. 7A, a stacked structure 110 is formed on a lower structure (not shown). The lower structure may include a substrate. The substrate may include a semiconductor material. The lower structure further includes a peripheral circuit, interconnections coupled to the peripheral circuit, an insulation structure covering the peripheral circuit and the interconnections, and a source layer disposed over the insulation structure. The peripheral circuit is disposed on the substrate and controls operation of a memory cell array. The source layer corresponds to the source layer SL shown in FIG. 1.

The stacked structure 110 includes a plurality of first material layers 101 and a plurality of second material layers 103. Each of the first and second material layers 101 and 103 may have a shape of a flat panel or planar sheet that extends, for example, in an XY plane in the first direction DR1 and the second direction DR2. The first material layers 101 are alternately arranged with the second material layers 103 in the third direction DR3 orthogonal with the XY plane. The third direction DR3 may be a Z-axis direction and is referred to as a stacking direction.

The second material layer 103 has an etch selectivity relative to the first material layer 101. According to an embodiment, the first material layer 101 may include an insulating material such as a silicon oxide layer and the second material layer 103 may include a sacrificial insulating material such as a silicon nitride layer.

Referring to FIG. 7B, a plurality of holes 105 are formed by etching the plurality of first material layers 101 and the plurality of second material layers 103. The plurality of holes 105 are arranged in a plurality of rows and columns. Each of the holes 105 passes through the stacked structure 110. Though not shown, the hole 105 may be open to or expose the source layer of the lower structure.

A ferroelectric layer 111L is formed in the hole 105. The ferroelectric layer 111L includes a material having polarization characteristics affected by an applied electric field. According to an embodiment, the ferroelectric layer 111L may include a hafnium oxide-based material. The hafnium oxide-based material may be a hafnium oxide (HfO₂) or a dopant-doped hafnium oxide. The ferroelectric layer 111L extends in the third direction DR3 along inner walls of the plurality of first material layers 101 and the plurality of second material layers 103 exposed through the hole 105 and have a tubular structure. The ferroelectric layer 111L may include an orthorhombic crystal phase.

A channel layer 113 is formed to cover an inner wall of the ferroelectric layer 111L. The channel layer 113 may include a semiconductor material. According to an embodiment, the channel layer 113 may include silicon. The channel layer 113 may have a tubular structure. A core insulating layer 115 is formed in a central area of the channel layer 113. Though not shown, a capping semiconductor pattern may be disposed on an upper end of the core insulating layer 115.

Referring to FIG. 7C, a slit 117 is formed by etching the plurality of first material layers 101 and the second material layers 103 as shown in FIG. 7B. The slit 117 passes through the stacked structure 110 as shown in FIG. 7B and opens sidewalls of the plurality of second material layers 103.

The plurality of second material layers 103 as shown in FIG. 7B are selectively removed through the slit 117. As a result, a plurality of horizontal spaces 119 are formed. The plurality of first material layers 101 are divided by the slit 117 to form a mold structure MD.

Referring to FIG. 7D, a plurality of conductive layers 121A and 121B are disposed in the plurality of horizontal spaces 119 as shown in FIG. 7C. The plurality of conductive layers 121A and 121B are spaced apart from each other by the slit 117 in the first direction DR1 and the mold structure MD in the third direction DR3.

Referring to FIG. 7E, the plurality of first material layers 101 as shown in FIG. 7D are selectively removed through the slit 117 to remove the mold structure MD shown in FIG. 7D. An opening 135 is formed between the lower conductive layer 121A and the upper conductive layer 121B by removing the mold structure MD as shown in FIG. 7D. The plurality of conductive layers 121A and 121B are alternately arranged with a plurality of openings 135 in the third direction DR3 to form the gate stack structure 121.

Areas of the ferroelectric layer 111L are exposed through the openings 135. The ferroelectric layer 111L has an etch selectivity relative to silicon oxide forming the plurality of first material layers 101 as shown in FIG. 7D. Thus, the ferroelectric layer 111L may serve as a support that prevents the gate stack structure 121 from collapsing during an etch process that selectively removes the plurality of first material layers 101.

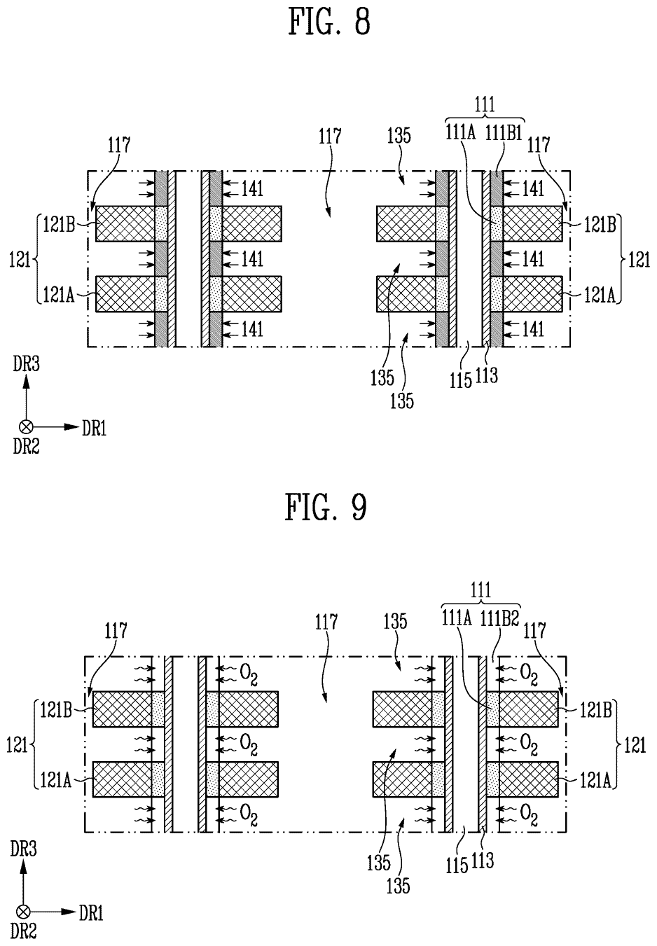

FIG. 8 shows cross-sections illustrating a non-ferroelectric area of a ferroelectric memory device formed using processes of forming non-ferroelectric areas of a ferroelectric memory device according to embodiments of the present disclosure.

Referring to FIG. 8, a dielectric layer 111 including non-ferroelectric areas 111B1 is formed by injecting a dopant 141 in some areas of the ferroelectric layer 111L shown in FIG. 7D. The dopant 141 may include one or more of zirconium (Zr), silicon (Si), aluminum (Al), gadolinium (Gd), yttrium (Y), lanthanum (La), and strontium (Sr). Spontaneous polarization characteristics of the non-ferroelectric area 111B1 of the dielectric layer 111 may be lost or reduced by controlling the doping concentration of the dopant 141.

During the process of doping the dopant 141, the dopant 141 is controlled such that areas of the ferroelectric layer between each of the conductive layers 131A and 121B and the channel layer 113 are not doped with the dopant 141. As a result, the areas of the ferroelectric layer between each of the plurality of conductive layers 121A and 121B and the channel layer 113 remain as ferroelectric areas 111A of the dielectric layer 111. The ferroelectric areas 111A are alternately arranged with the non-ferroelectric areas 111B1 in the third direction DR3.

After the processes described in association with FIG. 8 are performed, an insulating layer may be formed in the slit 117 such that an air-gap is formed in each of the openings 135. As a result, the ferroelectric memory device as described above with reference to FIG. 5A and FIG. 5B is formed.

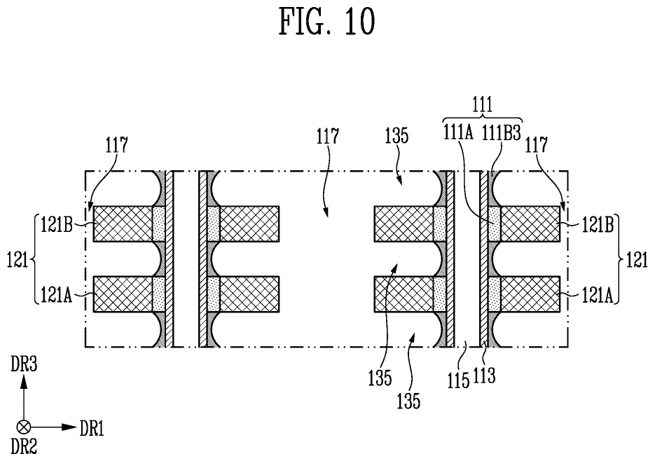

FIG. 9 and FIG. 10 are cross-sectional diagrams illustrating a non-ferroelectric area of a ferroelectric memory device formed using post-processing of a non-ferroelectric area according to embodiments of the present disclosure.

Referring to FIG. 9, after the processes described in association with FIG. 8 are performed, an oxygen O₂ annealing process may be performed through the openings 135. The oxygen O₂ annealing process is performed such that a crystal system of the non-ferroelectric area 111B1 shown in FIG. 8 is changed. As a result, a non-ferroelectric area 111B2 having a different crystal system or structure from the non-ferroelectric area 111A is formed. The non-ferroelectric area 111B2 includes at least one of an antiferroelectric area and a paraelectric area. The ferroelectric area 111A may have an orthorhombic crystal phase. The antiferroelectric area may have a tetragonal crystal phase. The paraelectric area may have a monoclinic crystal phase. After the processes described in association with FIG. 9 are performed, an insulating layer may be formed in the slit 117. As a result, the ferroelectric memory device as described above with reference to FIG. 6A is formed.

Referring to FIG. 10, after the processes described in association with FIG. 8 are performed, the openings 135 may be extended by etching the non-ferroelectric area 111B1 shown in FIG. 8 through the openings 135. A sidewall of the remaining non-ferroelectric area 111B3 may have a concave structure due to the etching process. After the processes described in association with FIG. 10 are performed, an insulating layer may be formed in the slit 117. As a result, the ferroelectric memory device as described above with reference to FIG. 6B is formed. The present disclosure is not limited to this example. According to another embodiment, after the processes described in association with FIG. 7E are performed, the openings 135 may be extended by etching areas of the ferroelectric layer 111L, shown in FIG. 7E, through the openings 135. Subsequently, as described above with reference to FIG. 8, a dopant is injected through the openings 135.

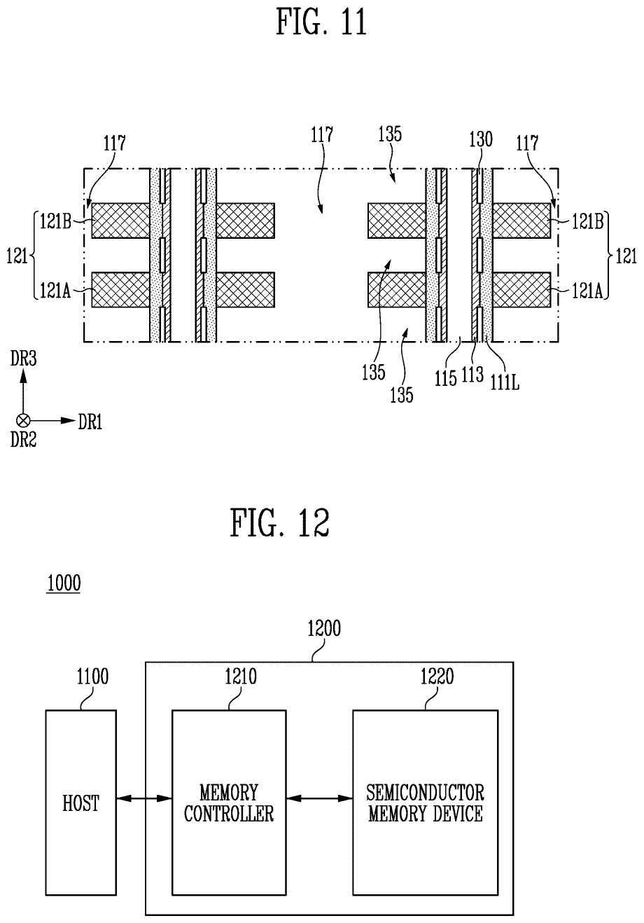

FIG. 11 is a cross-sectional diagram illustrating an interface oxide layer formed using a process according to an embodiment of the present disclosure.

Referring to FIG. 11, after the processes described in association with FIG. 7E are performed, an area of the channel layer 113 is oxidized through the openings 135. During an oxidation process, oxygen permeates the ferroelectric layer 111L through the openings 135 to oxidize the area of the channel layer 113. As a result, an interface oxide layer 130 is formed between the ferroelectric layer 111L and the channel layer 113. After the interface oxide layer 130 is formed, the processes as described with reference to FIG. 8 are performed. As a result, the ferroelectric memory device as described with reference to FIG. 6C is formed. The present disclosure is not limited to this example. After the interface oxide layer 130 is formed, the subsequent processes as described with reference to FIG. 9 may be performed, or the subsequent processes as described above with reference to FIG. 10 may be performed.

FIG. 12 is a block diagram illustrating an electronic system 1000 according to an embodiment of the present disclosure.

Referring to FIG. 12, the electronic system 1000 may include a computing system, a medical device, a communication device, a wearable device, or a memory system. The electronic system 1000 includes a host 1100 and a storage device 1200.

The host 1100 stores data in the storage device 1200 and reads the stored data from the storage device 1200 in response to signals constructed according to an interface. The interface may include at least one of a Double Data Rate (DDR) interface, a Universal Serial Bus (USB) interface, a multimedia card (MMC) interface, an embedded MMC (eMMC) interface, a peripheral component interconnection (PCI) interface, a PCI-express (PCI-E) interface, an Advanced Technology Attachment (ATA) interface, a Serial-ATA interface, a Parallel-ATA interface, a small computer system interface (SCSI), an enhanced small disk interface (ESDI), an Integrated Drive Electronics interface (IDE), a Firewire interface, a Universal Flash Storage (UFS) interface, and a Nonvolatile Memory express (NVMe) interface.

The storage device 1200 includes a memory controller 1210 and a semiconductor memory device 1220. According to an embodiment, the storage device 1200 may be a solid state drive (SSD), a universal serial bus (USB) memory, or the like.

The memory controller 1210 stores data in the semiconductor memory device 1220 and reads data stored in the semiconductor memory device 1220 in response to control of the host 1100.

The semiconductor memory device 1220 may include a single memory chip or a plurality of memory chips. The semiconductor memory device 1220 may store data or output stored data in response to control of the memory controller 1210.

The semiconductor memory device 1220 is a ferroelectric memory device, for example, as described with respect to FIG. 1 through FIG. 11. The ferroelectric memory device includes a dielectric layer interposed between a channel layer and a conductive layer of a gate stack structure. The dielectric layer includes a ferroelectric areas surrounding the conductive layer and a non-ferroelectric areas separating the ferroelectric areas.

According to the present disclosure, operational reliability of a ferroelectric memory device may be improved by dividing or separating a ferroelectric areas using a non-ferroelectric areas.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A ferroelectric memory device comprising:
a dielectric layer including a plurality of ferroelectric areas alternately arranged with a plurality of non-ferroelectric areas in a first direction, the dielectric layer having a tubular structure;
a channel layer extending in the first direction on an inner wall of the dielectric layer; and
a gate stack structure including a plurality of conductive layers surrounding the plurality of ferroelectric areas of the dielectric layer, wherein the plurality of conductive layers are spaced apart in the first direction.

2. The ferroelectric memory device of claim 1, wherein the dielectric layer includes a hafnium oxide-based material.

3. The ferroelectric memory device of claim 1, wherein:
the plurality of ferroelectric areas include hafnium oxide (HfO₂), and
the plurality of non-ferroelectric areas include silicon-doped hafnium oxide (HSO).

4. The ferroelectric memory device of claim 1, wherein:
the dielectric layer includes a hafnium oxide-based material doped with a dopant, and
the dopant includes one or more of zirconium (Zr), silicon (Si), aluminum (Al), gadolinium (Gd), yttrium (Y), lanthanum (La), and strontium (Sr).

5. The ferroelectric memory device of claim 1, wherein each of the ferroelectric areas and the non-ferroelectric areas of the dielectric layer includes silicon-doped hafnium oxide (HSO), and
a concentration of the silicon is greater in the plurality of non-ferroelectric areas than in the plurality of ferroelectric areas.

6. The ferroelectric memory device of claim 5, wherein the concentration of the silicon is 4% or more and less than 9% in the plurality of ferroelectric areas, and is 9% or more in the plurality of non-ferroelectric areas.

7. The ferroelectric memory device of claim 5, further comprising a silicon dioxide (SiO₂) layer interposed between each of the plurality of ferroelectric areas and the channel layer.

8. The ferroelectric memory device of claim 1, wherein the plurality of non-ferroelectric areas have a different crystal system than the ferroelectric areas.

9. The ferroelectric memory device of claim 1, wherein each of the plurality of non-ferroelectric areas includes an antiferroelectric area and a paraelectric area.

10. The ferroelectric memory device of claim 1, wherein each of the plurality of ferroelectric areas includes an orthorhombic crystal phase, and
each of the non-ferroelectric areas includes at least one of a tetragonal crystal phase and a monoclinic crystal phase.

11. The ferroelectric memory device of claim 1, wherein each of the plurality of non-ferroelectric areas includes a concave outer wall that faces in a direction away from the channel layer.

12. The ferroelectric memory device of claim 1, further comprising:
an insulating layer covering a sidewall of the gate stack structure; and
an air-gap formed between consecutive conductive layers of the plurality of conductive layers and adjacent to the insulating layer.

13. A ferroelectric memory device comprising:
a gate stack structure including a plurality of conductive layers spaced apart in a first direction;
a dielectric layer disposed within the gate structure and including a plurality of ferroelectric areas forming memory cells alternately arranged with a plurality of non-ferroelectric areas in the first direction; and
a channel layer disposed on an inner wall of the dielectric layer.

14. A method of manufacturing a ferroelectric memory device, the method comprising:
forming a stacked structure including a plurality of first material layers alternately arranged with a plurality of second material layers in a stacking direction;
forming a hole passing through the stacked structure by etching the plurality of first material layers and the plurality of second material layers;
forming a ferroelectric layer in the hole, the ferroelectric layer having a tubular structure extending in the stacking direction;
forming a channel layer extending in the stacking direction and covering an inner wall of the ferroelectric layer;
forming a slit passing through the stacked structure by etching the plurality of first material layers and the plurality of second material layers;
replacing the plurality of second material layers with a plurality of conductive layers through the slit;
removing the plurality of first material layers through the slit such that an opening is formed between consecutive conductive layers of the plurality of conductive layers in the stacking direction; and
injecting a dopant into areas of the ferroelectric layer exposed through the opening such that a plurality of non-ferroelectric areas is formed in the ferroelectric layer.

15. The method of claim 14, wherein an area of the ferroelectric layer between each of the conductive layers and the channel layer forms one of a plurality of ferroelectric areas, and the plurality of ferroelectric areas are alternately arranged with the plurality of non-ferroelectric areas in the stacking direction.

16. The method of claim 14, further comprising forming an interface oxide layer between the area of the ferroelectric layer exposed through the opening and the channel layer.

17. The method of claim 14, wherein the non-ferroelectric area includes at least one of an antiferroelectric area and a paraelectric area.

18. The method of claim 14, further comprising, after injecting the dopant, changing a crystal system of the non-ferroelectric area.

19. The method of claim 14, further comprising post-processing the non-ferroelectric area through the opening by oxygen annealing such that the non-ferroelectric area includes at least one of a tetragonal crystal phase and a monoclinic crystal phase.

20. The method of claim 14, further comprising, after injecting the dopant, etching the non-ferroelectric area to extend the opening.

21. The method of claim 14, further comprising forming an insulating layer in the slit to form an air-gap in the opening.
